(19) United States
(12) Patent Application Publication
(10) Pub. No.: US 2004/0090760 A1
(43) Pub. Date: May 13, 2004

(54) Electrical connecting element and method of fabricating the same

(76) Inventor: Walter Schmidt, Russikon (CH)

Correspondence Address: RANKIN, HILL, PORTER & CLARK, LLP, 925 EUCLID AVENUE, SUITE 700, CLEVELAND, OH, 44115-1405, US

(21) Appl. No.: 10/239,732

(22) PCT Filed: Mar. 29, 2001
(86) PCT No.: PCT/CH01/00193

(51) Int. Cl. H05K 1/11; H05K 1/14

(52) U.S. Cl. 361/803

(57) ABSTRACT

The electrical connecting element includes an essentially stiff core, essentially mechanically stiff and printed circuit boards and/or high density interconnects with conductor paths serving as interconnects. The core includes two parts (1, 3) that can be fixed to each other. Between the two parts, a cavity (101) can be formed. Components (103) producing a lot of heat or requiring protection from environmental influences can be placed in the cavity.

### BACKGROUND OF THE INVENTION

1. FIELD OF THE INVENTION

The present invention relates to electrical connecting elements such as Printed Circuit Boards (PCBs), High-Density-Interconnects (HDIs), Ball-Grid-Array-(BGA-) substrates, Chip Scale Packages (CSP), Multi-Chip-Module-(MCM) substrates, etc. The present invention also relates to a method for fabricating an electrical connecting element or a semi-finished product, respectively.

2. Description of Related Art

In the past, electrical connecting elements, mainly in the form of printed circuit boards, were considered as relatively simple items. Nowadays, however, electrical connecting elements have become increasingly complex. This, in particular, is because more and more functions have to be performed by an electrical connecting element. In the past, a PCB primarily had to fulfill the following functions:

to provide a mechanical carrier for the passive and/or active circuit components (rigidity);

to provide electrical power connections (Vcc) to the power consuming components and the return path (GND) (power supply);

to provide conductor lines to conduct signals from one component to the others (signal distribution);

to provide appropriate mechanical and/or electrical interfaces to the components and to the external world (interfaces);

in some high power applications, to provide for heat removal from power consuming components (heat sink)

In the future, additional burdens will be loaded into PCBs or HDIs because new requirements related to modern electronics arise. These additional burdens include:

to provide accurately defined impedance values on certain high frequency signal tracks. This means that the signal line obtains a vital, active role in the function of the circuit (signal integrity).

to provide shielding layers to avoid electromagnetic interference between signal lines and/or between signal lines and power supply lines or the external world (emission or pick up electrical signals, EMI);

to provide embedded passive components like resistors, capacitors and inductors as well as thinned integrated circuit chips, which also are buried into the electrical connecting element substrate (embedded components);

to provide optical interconnects by having integrated glass fibers or other means as optical wave guides as well as optical splitters, combiners and other optical components like mirrors, prism, etc. (optical signal distribution);

to provide a possibility to dismantle a PCB/HDI easily into pure “clean” materials, which preferable should be recyclable or reusable. In addition, the manufacturing processes have to be “clean” also and the use of natural resources like water or energy should be minimized (environmental impact).

In addition to the inflation of burdens, the electrical connecting element has to be manufactured with very fine features and with constantly lower cost.

In order to address this general problems related to modern interconnect substrates, a new architectural concept has to be introduced.

First beginnings of such a concept have been presented already in EP-A-0 451 541 and PCT/CH96/00218. They are based on the “Separation of Functions” (SOF) philosophy. The basic idea is to allocate one or a limited number of functions to just one constructive element as opposed to the “Amalgamation of Functions” (AOF) philosophy, which tries to load as many functions as possible on one element.

Another advantage of the SOF philosophy has also been demonstrated in U.S. Pat. No. 5,819,401: If the function “rigidity” is taken over by a separate element, the PCB/HDI substrate must itself not provide for the rigidity any more. According to the teaching of this patent, two PCBs with conventional vias are each bonded to one side of a metal core. A pin connection through an opening in the metal core is present so that the two HDIs can exchange information and/or electrical energy. The connection pins are soldered to contact areas of the HDIs.

However, in spite of its advantages, this set-up has a somewhat limited flexibility. Especially, if a lot of components and/or large components have to be mounted on the PCB, the real estate on the layers is quickly used up. In addition, the connection problem is not satisfactorily solved. U.S. Pat. No. 5,819,401 discloses a pin connection between the two two-layer PCBs across the core. The pins penetrate through the PCBs and are soldered to them at the outsides of the set-up. This solution, however, opens up only restricted communication opportunities and may not do justice to the sophisticated possibilities modern HDI technology offers. Further, again mechanically drilled holes have to be processed in the PCB/HDI substrates, also covering a large real estate area. Also, once the pins are soldered to the PCBs, the set-up can not easily be dismantled any more and exchanging single components is impossible.

A further possibility to electrically connect PCBs arranged on two sides of a rigid item is an edge clip connection. Such a connection, however, covers a large space and may result in signal line loops, which are prohibited in high frequency applications.

Another important item relates to bandwidth. In future applications, the operating bandwidth of PCB/HDI substrates will generally be much higher than today. Video signals with bit-rates up to 10 or more Gb/sec will be requested and electrical signal lines approach technical limits. An answer to this challenge is optical interconnect. Optical transparent glass fibers are already widely used for the transmission of data over long distances and have proven to be very suitable.

One drawback of this technology is the fact that, today, the optical-electrical conversion is not an integral part of the IC chips and has to be done off-chip. This increases the cost considerably and also requires performance compromises. In the future, these problems possibly will be solved. However, although the distribution of optical signals within a PCB/HDI can be performed relatively easily, by laying down a glass fiber onto the board, the various passive and active optical components have to be aligned extremely precisely to each other in order not to lose energy and cause reflections and change of the polarization direction. Also, the thermal expansion of organic substrates is usually quite high, i.e. in the range of 30-100 ppm/K, and this causes mechanical deformation and misalignment of the optics.

In addition to the strongly increasing technical pressure put onto the PCB/HDI industry, environmental aspects are getting very important too. Not only the actual problem of using clean materials, processes etc. and the need to recycle or reuse parts or to dispose electronic scrap safely is driving the game, environmental issues are becoming more and more a marketing instrument.

A new build-up concept, therefore, must promise a solution to this problem area as well. The problem can be divided into product related issues and process related issues.

Product related issues include:

Use of base materials with no harmful adds like halogens or other problematic flame inhibitors;

Build-up concept, which allows an easy dismantling process into pure fractions of materials, which can be recycled or even reused;

Use of lead-free solders or other connection methods;

Minimized material usage.

Process related issues include:

Use of clean manufacturing processes with no or minimum environmental impact;

Minimized use of natural resources like water, air or power; and,

Use of processes with inherently high yield to minimize process related scrap.

### SUMMARY OF THE INVENTION

It is therefore an object of the present invention to overcome drawbacks of the prior art electrical connecting elements and especially to provide an electrical connecting element that is based on the hard core idea but which offers more flexibility and new setup design opportunities. The electrical connecting element should preferably provide solutions to the previously mentioned problem areas.

Especially, the invention should also provide opportunities for a satisfactory integration of optical connections that do not suffer from drawbacks of the prior art optical connections.

The invention is essentially characterized in that a mechanically stiff core comprises two parts.

In accordance with an embodiment of the invention, signal carrying PCB/HDI substrate(s) can be made out of very thin, flexible dielectric materials. This allows to work with microvias only and does not require any mechanical drilling of holes through glass-reinforced epoxy material. By eliminating mechanical drilling and replacing it by a microvia drilling technology (see e.g. WO 00/13062), the diameter of the lands needed for these microvias is drastically reduced from 500-1000 μm to 150-300 μm, resulting in a massive real estate saving on the signal layers. Thus, the number of signal layers required to lay out a circuit substrate is reduced to a minimum of two. In exceptional, complex cases, however, more than 2 signal layers are needed. When such a substrate with signal tracks on both sides and electrically connected from one side to the other by plated microvias is sandwiched between two additional layers, carrying ground and power supply, the final build-up becomes a 4-layer structure, which can be thinner as 500 μm and as thin as 200 μm or less, capable of replacing a conventional PCB or HDI with 10-20 layers.

The very thin build-up promises the solution of an other problem: Heat removal. When the thin PCB/HDI is bonded to a metal core, the thermal path gets very short and a lot of heat can be conducted from component to the core, which, due to the high heat conductivity of the metal, conducts the heat effectively to the thermal interfaces where it is taken away to a cold housing, etc.

In this way, the SOF concept results in a much better performing element and in addition uses less organic material and also allows an easy separation of organic from metal material (environmental impact).

Because the number of layers required is limited to four, the thickness of the PCB/HDI is almost given. When the core is designed also with unified thickness, the complete build up has a unified thickness, too. Thus, the electrical and mechanical interfaces of such a construction can be unified and standardized, which allows the use of standard materials, etc.

The fact that, according to the invention, a core having two parts is present, also makes possible more efficient electrical connections. This allows an easy separation of the two sides. Before the two sides are actually mounted together, the micro-connectors can also serve for test purposes. Further, due to the invention, the connector can take over additional functions and, for example, can be formed as a distributor board. Then, also a lateral distribution of signals and/or power lines can be done outside the PCB/HDIs as such and, thus, additionally to their distribution capabilities.

A further advantage of the invention is that it makes possible for optical connections to be mounted into the rigid core. The core, then, can be made out of a material, which features a low coefficient of thermal expansion (CTE).

A still further advantage of the invention is that components can be integrated in a cavity inside the core. As an example, a passive or active component producing a lot of heat and/or being of considerable size can be placed inside such a cavity. If components producing a lot of heat are placed inside the cavity, the PCB/HDIs are relieved from a burden, namely the burden of also being responsible for heat removal. In addition, thermal strain in the PCB/HDIs is reduced. A metallic core, as an other example, also provides excellent shielding for any components sensitive to electromagnetic noise placed inside the cavity. Also, components sensitive to mechanical damages are well protected in a cavity in the core. The same holds for components sensitive to environmental influences such as chemical substances, light, sound, humidity, etc.

A cavity in the core is especially suited for entire optical set-ups. Optical set-ups usually have to be aligned very carefully and precisely. Integration into PCBs so far has proven to be difficult, the compromises to be made therefore unsatisfactory. For example, the coefficient of thermal expansion and other parameters leading to material distortions of plastics suited as PCB substrates make them not suited as substrates for optical set-ups. Integration of optical waveguides into PCB setups may lead to rugged waveguide surfaces and, accordingly, to considerable losses. Additionally, stray light from the environment may disturb the transmission of optical signals. Optical set-ups integrated into the core, however, may be mounted on especially designed substrates and be perfectly shielded from environmental influences, well in line with the SOF philosophy.

The build-up concept according to the invention also allows to comply completely with the environmental requirements. Various materials can be used in a combination, which can easily be dismantled and recycled or reused.

Due to the favorable architecture, the electrical connecting element allows that the general, fundamental advantages of the SOF philosophy fully pay off. These advantages are basically are as follows: if each function is taken over by a different element, the optimal parameters (material, design etc.) can be optimized for each function separately. In this way, a new degree of freedom is gained in the choice of materials, the design opportunities and so on. This can not only be used for optimizing functionality and reliability, but also to reduce cost and increase production efficiency. Further, also testing of separate functions is easier and more efficient.

As an example, for a specific function, high-end, mid-end, and low-end elements can be produced as off-the-shelf items and be arbitrarily combined with elements for other functions according to the specific requirements. For instance, in a power supply application, the packaging and wiring density is usually not an issue, but the dissipated heat is very high and requires a high-end core material. In an application like a mobile phone, packaging density is the first priority, but heat dissipation is not a problem at all. SOF allows to optimize the quality of the components used instead of trying to maximize it.

### BRIEF DESCRIPTION OF THE DRAWINGS

These and further features of the invention will be apparent with reference to the following description and drawings, wherein:

FIG. 1 shows the principle of a first embodiment of the invention, i.e. a single sided assembly;

FIG. 2 shows the principle of a second embodiment of the invention, i.e. a double sided assembly;

FIG. 3 schematically represents a PCB/HDI build-up according to the invention and the heat dissipation;

FIGS. 4a through 4d show various options to generate electrical connections from one side to the other side of the build-up;

FIGS. 5 and 6 very schematically show the principle of an embodiment of the invention with an optical connection;

FIGS. 7 and 8 schematically represent an embodiment of the invention with a representation of external interface;

FIGS. 9a and 9b represent an embodiment of the invention with an embedded component;

FIG. 10 shows a build-up with off-the-shelf internal interface means; and,

FIG. 11 represents a scheme of the dismantling process of an electrical connecting element according to the invention.

### DETAILED DESCRIPTION OF THE PREFERRED EMBODIMENTS

In the following description, electrical connecting elements comprising a hard core and foil PCB/HDIs attached to them are described. In order to simplify the terminology, the entire set-up is called “electrical connecting element” and the foil PCB/HDIs being part of it are called “PCB/HDI”. It goes without saying that the entire set-up can as well have the function of a PCB/HDI and that the foil elements neither do have to be a PCB/HDI in the conventional sense nor do they have to be made foil-like. They can, in fact, be substrates for passive and/or active components of any kind. They may be fabricated with a more or less conventional PCB or HDI manufacturing technique. As an alternative, they may also be fabricated by a new or yet to develop technique, and especially with a technique that makes the fabrication of very fine structures possible.

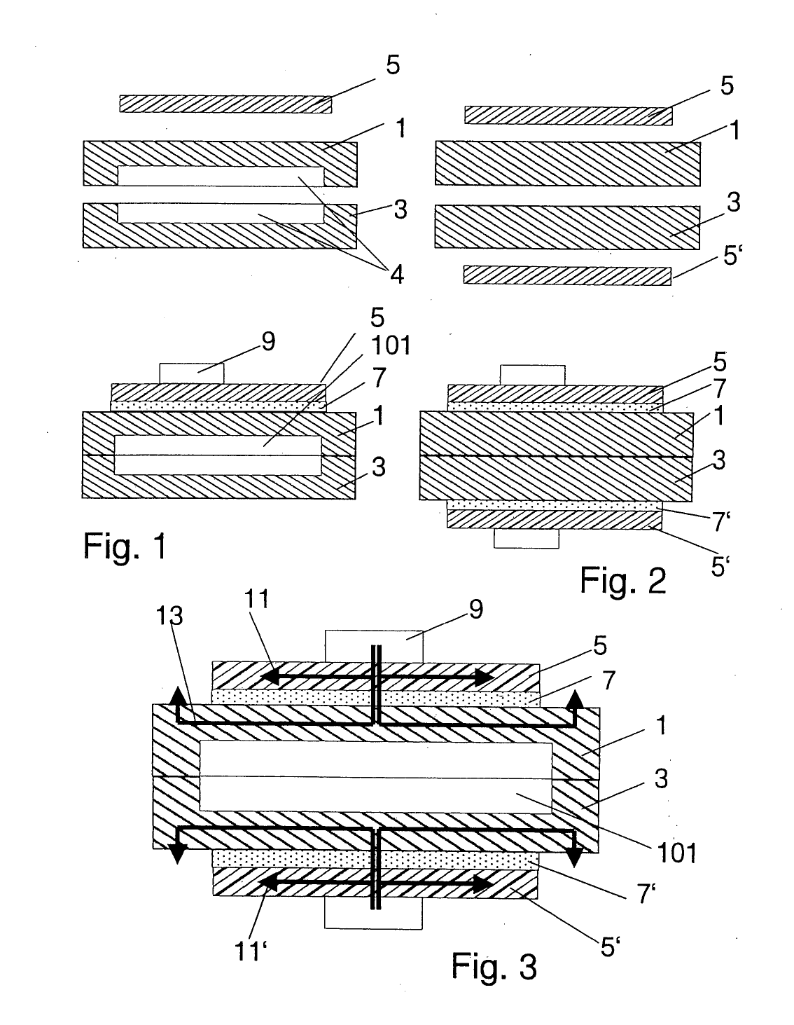

The core represented in FIG. 1 is made of two parts 1, 3. Like the core of all the following figures, it is made of any material that provides the desired mechanical stiffness and the desired heat dissipation rate. Preferably, but not necessarily, the parts are made of the same material or materials. In general, the core material should fulfill a number of requirements, of which some are contradictory. These requirements include:

The material should have a high heat conductivity;

The material should provide a sufficient rigidity;

It should be a low cost material;

It should be a material, which can be formed (sculptured) very easily and economically.

The best solution for many applications are die-castable materials based on Magnesium and Aluminum. These low-cost materials can be sculptured very precisely and economically—as proven by the automotive industry—to almost any shape by die casting. If special requirements, like very high heat conductivity or low (coefficient of thermal expansion) CTE values are a must, composites of these materials with copper, Invar or other special materials can be taken. Depending on the application, the two core parts 1, 3 may also be made of plastic, such as PVC or a glass fiber reinforced plastic. Of course, also other metals or non-metals can be used.

The parts 1, 3 may be mechanically fixed to each other by any known fixation means. They, for example, comprise recesses 4, due to which, in the assembled state, a cavity 101 is formed.

The electrical connecting element of FIG. 1 further to the core 1, 3 comprises a foil High Density Interconnect (HDI) 5. This HDI may be a known and tested HDI. The HDI is mounted on the core by means of an interface layer 7, e.g. a thin epoxy layer or any other known or new interface means. On the surface of the HDI facing away from the core, any number of active and/or passive components 9 may be mounted. If at least some of the components 9 are susceptible to warming, the interface layer will preferably be an adhesive with a high thermal conductance.

The electrical connecting element shown in FIG. 2 is based on the same principle as the electrical connecting element of FIG. 1. It, however, comprises two HDIs 5, 5′ mounted on each side of the core 1, 3 by interface means 7, 7′. In the example shown in FIG. 2, no cavity is formed.

As schematically represented in FIG. 3, due to the set-up according to the invention, more and more efficient channels are available for heat dissipation. Next to lateral heat dissipation on the HDI—or PCB itself, as represented by arrows 11, 11′, also heat dissipation via the core is possible (arrow 13). Due to the reduced thickness of foil PCB/HDIs this channel will generally be dominant. The reduced thickness of these PCB/HDIs is also responsible for the fact that ‘vertical’ heat dissipation from the passive and/or active component(s) 9 to the core 1, 3 is efficient.

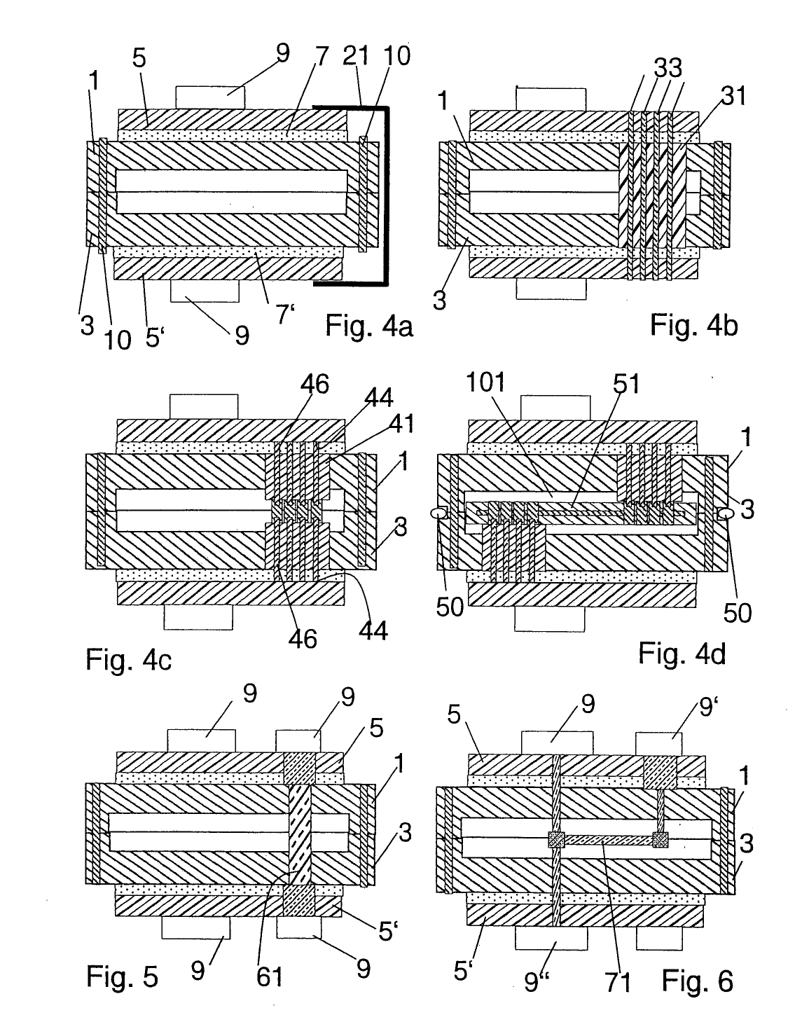

Very often, the two sides of a double sided assembled board have to talk to each other electrically or also optically. FIGS. 4a-4d are four different methods illustrating how electrical interconnects can be integrated and, thus, demonstrate the flexibility made possible by the invention.

An edge clip connector 21 as shown in FIG. 4a is per se already known. Such a connector 21 is externally mounted on one or several sides of the board and electrically connects the two PCB/HDIs across connection paths. This method requires all signal lines running from top to bottom to be routed to the periphery of each PCB/HDI. Thus, usually a lot of space is covered and signal line loops may be created, which adversely affect the high frequency parameters. Nevertheless, in many applications, this technique is good enough.

Also shown in the figure, as in some of the subsequent figures, are alignment and/or connection means 10. These means may comprise pins guided by openings in the core 1, 3. They may further comprise attachment means, such as screws.

The connection of FIG. 4b is a through connection 31 integrated into the core. The through connection 31 comprises a plurality of pins 33 mounted inside the core 1, 3 and electrically isolated from the core. This pin contacting technique, despite the disadvantages mentioned in the introduction section of this text, can be used if the packaging density is not too high and a relatively high cost level is acceptable.

The electrical connecting element of FIG. 4c, in contrast to the element of FIG. 4b, goes two steps further. A first step consists of introducing an electrical connection between the PCB/HDIs and a pin by contact. Due to the contact, no through hole through the PCB/HDIs are required. Instead, contact areas 44 at the surface of the PCB/HDIs pointing towards the core are contacted. The contact may be either made up of spring-loaded pins 46 pressed permanently toward contact pads arranged on the back side of the PCB/HDIs or by solder coated pins providing a solder connection as soon as the electrical connecting element is heated above the melting temperature. According to a second step, the pins are not going through from one side to the other. In the center of the core, i.e. between the parts 1, 3, a micro-connector 41 is mounted. This micro-connector is, for example, an assembly of electrical contacts of any kind. Known contacts, e.g., comprise pins being made of wound up thin wire or fibers of an elastic conducting material such as thin Tungsten wire, pressing against a contact surface. Also, other contacts having a pin or the like pressing applying pressure along its longitudinal axis against a contact surface belong to the state of the art. Other known contacts comprise two metal rings connected by wires, the rings being twisted against each other. The wires of this contact are, depending on the relative position of the two rings, laterally pressed against a surface, such as a pin surface. Also, other spring means laterally touching a pin to be contacted can be used. The micro-connector connects the pins from one half with the pins from the other half. This allows an easy separation of the two sides. Before the two sides are actually mounted together, the micro-connectors can also serve for test purposes.

A still further step in the development of through connections is described with reference to FIG. 4d. In the cavity 101 between the two parts 1, 3, a distribution board 51 is mounted in the center of the core. The distribution board may be a conventional Printed Circuit Board (PCB) and may have micro-connectors placed on specific locations as well as conductor tracks between the micro-connectors according to the needs given by the application, allowing the distribution of signals in the x/y direction. The distributor can be designed in a unified version, which means that it can be manufactured in larger volumes and can be applied for many different PCB/HDI designs.

Sealing means 50 are also shown very schematically in FIG. 4d. The sealing means 50 protect the components inside the cavity 101, i.e. the distributor board 51, from environmental influences. Of course, any know sealing means may be used for this purpose. Sealing means may especially be used if, as described with reference to the following figures, delicate components are placed inside the cavity. Although in the following figures such sealing means are not explicitly shown, it will be understood that, depending on the purpose of the device, they may be present to protect the inside of the cavity 101.

FIG. 5 schematically shows an optical through connector 61 basically consisting of a precisely aligned optical wave guide, which transmits signals vertically from components 9 of one PCB/HDI 5 to components of the other PCB/HDI 5′.

As can be seen from FIG. 6, the split core according to the invention also allows a satisfactory solution for the problem of optically connecting different components mounted on the same PCB/HDI 5. The optical signal line 71 connects three chips 9, 9′, and 9″ on the same PCB/HDI 5.

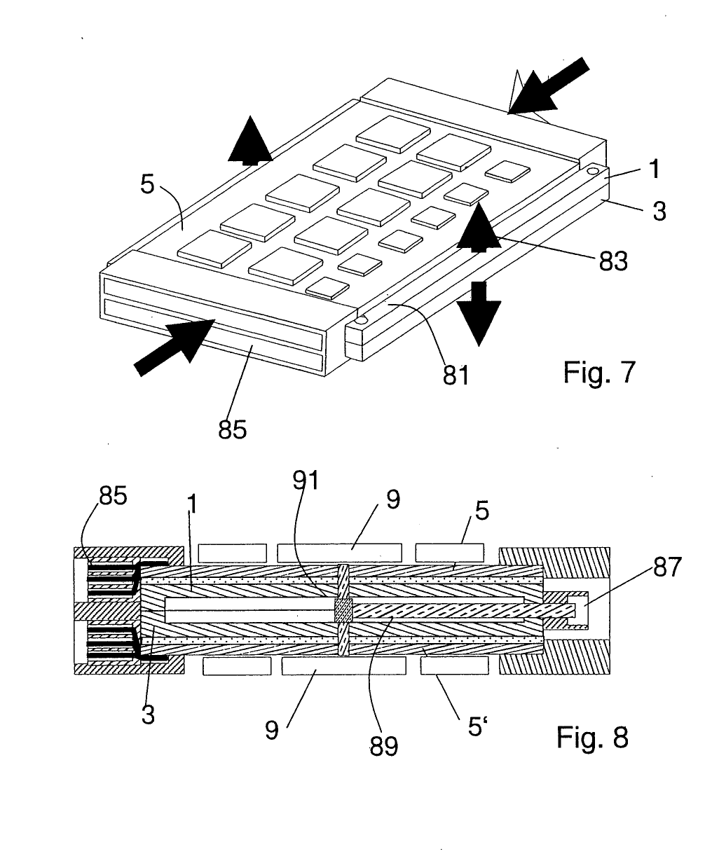

Electrical connecting elements according to the invention can also be efficiently connected to external devices. An overview on external interfaces is shown FIG. 7. FIG. 8 shows a schematic picture of a cut through the board and the connectors. As was previously explained, the split core 1, 3 serves to laterally conduct heat from the possibly very thin PCB/HDIs 5, 5′. Heat drains, which may be connected at the sides 81 of the electrical connecting element, may then remove the heat. This process is symbolized by arrows 83 in FIG. 7. To do this efficiently, the PCB/HDIs 5, 5′ are cut back on two sides of the board arrangement. These areas can be used to connect the board thermally to the rack or housing serving as heat drains.

The standardized set-up also allows mounting of standardized electrical interfaces and optical interfaces. The electrical interface 85 may be built as a special surface mount connector 85, serving both PCP/HDIs of the double sided assembly mounted on one side of the board arrangement. This connector provides the power and ground lines as well as the signals. On the other side of the board, a special optical connector 87 serving as an optical interface is placed. The optical connector 87 guides the optical signals via an optical wave guide 89 into the center of the core 1, 3 where the signals can be reflected up or down by micro-optical components 91. It is also possible for the optical connector to be integrated into the electrical connector 85.

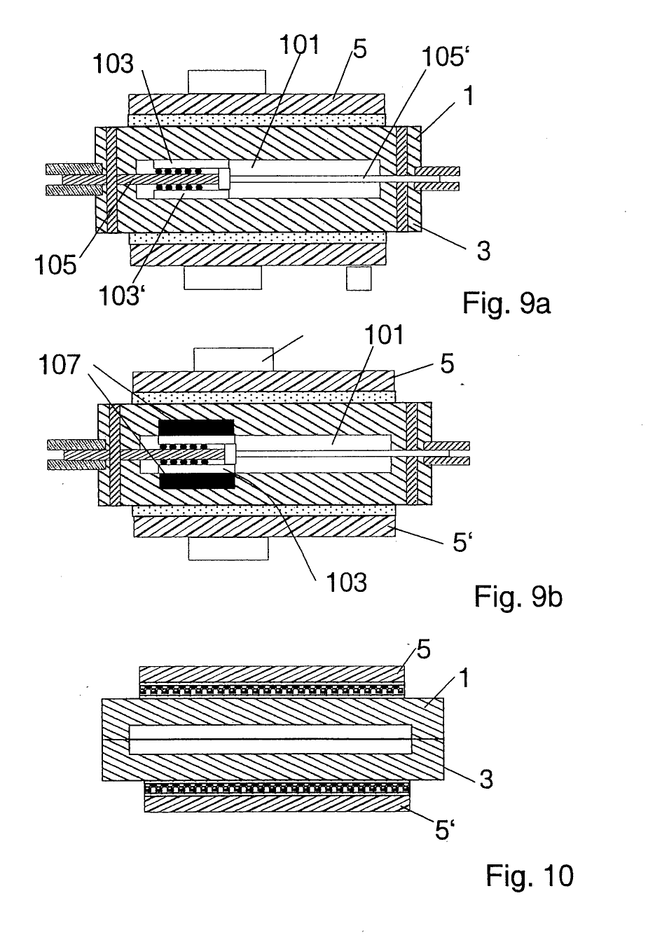

A crucial advantage of the invention becomes apparent from the embodiment of the invention shown in FIGS. 9a and 9b. According to this embodiment, the core 1, 3 again is at least partially hollow. A large variety of components can then be placed in the cavity 101. It goes without saying that, as in the examples described above, the cavity 101 does not have to be a complete cavity surrounded by walls but can also be partially open toward the exterior. As an extreme example, the core may comprise two shells that abut each other only at some peripheral locations and are fixable to each other.

In the following, a few examples of devices that can be advantageously placed in the cavity 101 are given. In the drawings, only one example is illustrated. However, the other examples are equally important and are suited for being applied with the invention.

According to the example shown in FIG. 9a, two processor chips 103, 103′, producing a lot of heat and/or being of considerable size are placed directly inside the cavity 101. The processor chips are connected to the PCB/HDIs and to the external world by electrical and optical connection means 105, 105′. If components producing a lot of heat are placed inside the cavity, the PCB/HDIs are relieved from the burden of also being responsible for heat removal. In addition, thermal strain in the PCB/HDIs is reduced. If required, additional heat pipes 107 having thermal contact with the processor chip 103 can be placed inside the core.

A metallic core 1, 3 also provides excellent shielding for any components sensitive to electromagnetic noise placed inside the cavity.

Also, components sensitive to mechanical damage are well protected in the core cavity. The same holds for components sensitive to environmental influences such as chemical substances, light, sound, humidity, etc.

A cavity in the core is especially suited for optical set-ups. Such set-ups usually have to be aligned very carefully and precisely. Integration into PCBs so far has proven to be difficult, the compromises to be made therefore unsatisfactory. For example, the coefficient of thermal expansion and other parameters leading to material distortions of plastics well-suited as PCB substrates make them not well-suited as substrates for optical set-ups. Integration of optical waveguides into PCB setups may lead to rugged waveguide surfaces and, accordingly, to considerable losses. Additionally, stray light from the environment may disturb the transmission of optical signals. Optical set-ups integrated into the core, however, may be mounted on especially designed substrates and be perfectly shielded from environmental influences.

A general advantage of single components or a set-up of components being mounted in a cavity inside the core is that separate testing, replacing and even repairing is possible. State-of-the-art integrated solutions with electrical and optical components alongside with substrate parts ensuring mechanical stability suffer from the major drawback that a whole sophisticated and expensive setup has to be scrapped if one component is somehow damaged.

FIG. 10 shows a set-up with a split core 1, 3 in which other standardized components are integrated. As an example, also for the thermal contact between the PCB/HDIs 5, 5′ and the core and for supplying power to the PCB/HDIs, separate of-the-shelf elements can be used. Such elements are described in applications of the same inventor and applicant filed at the same filing date and having the same priority.

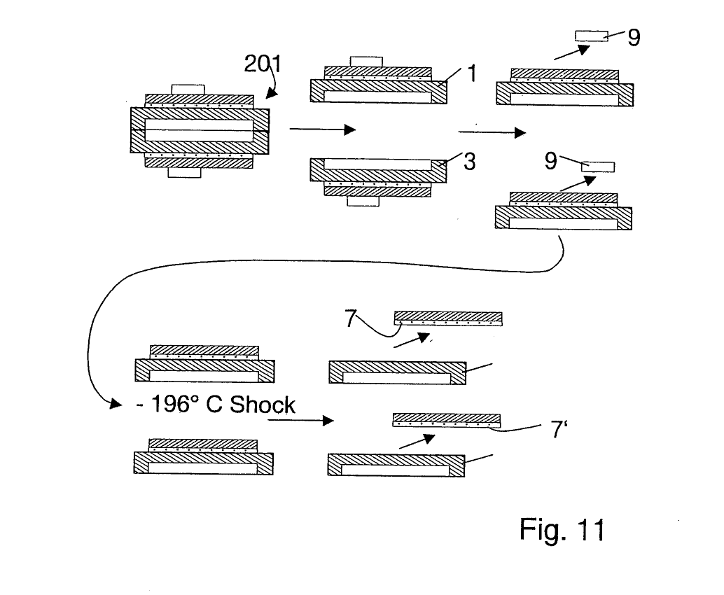

In FIG. 11, an example of a dismantling process at the end of a lifecycle of an electrical connecting element 201 according to the invention is presented; the sequence of the steps is shown by arrows. In a first step, the fixation of the two parts 1, 3 of the core is released. Then, the active and/or passive components 9 are removed. The PCB/HDIs can be separated from the core by, for example, thermal shock since the coefficients of thermal expansion largely differ between the core 1, 3 preferably made of metal and the dielectric substrates. The parts to be dismantled can, for example, be brought into contact with liquid nitrogen (temperature: −196° C.) or the like. The plastics at this temperature are very hard, adhesives 7, 7′ become brittle and the connections between core and PCP/HDIs loosen.

Of course, the sequence of the above process steps can be altered. The core 1, 3 being of standardized dimensions can possibly be reused.

Naturally, other embodiments of the invention may be envisaged. Also combinations of the features of the above embodiments may of course be implemented.

What is claimed is:

1. Electrical connecting element comprising a core, the core being essentially mechanically stiff and having attached to it at least one element (5, 5′) with conductor paths serving as interconnect, wherein the core comprises two parts (1, 3) which can be fixed to each other.

2. Electrical connecting element according to claim 1, wherein the parts (1, 3) of the core are made of metal and wherein the interconnect (5, 5′) comprises a bendable dielectric substrate foil, each side of which is partially covered with a conducting layer forming conductor paths, the foil further comprising microvias for electrically connecting conductor paths of the two conducting layers.

3. Electrical connecting element according to claim 1 or 2, wherein the parts (1, 3) of the core are made of metal and wherein the interconnect (5, 5′) comprises a multi-layered structure of conducting and non-conducting layers.

4. Electrical connecting element according to any one of the preceding claims comprising two interconnects (5, 5′), each attached to one part of the core (1, 3), wherein the two core parts (1, 3) comprise an opening (42) and electrical connections (46) in said opening, the electrical connections connecting contact areas (44) of the two interconnects (5, 5′).

5. Electrical connecting element according to claim 3, further comprising a microconnector (41) between the core parts (1,3) contacting contact means (46) for contacting each of the interconnects (5, 5′).

6. Electrical connecting element according to claim 3 comprising a distributor board arranged between the core parts (1, 3) and having contact areas for being contacted by contact means to each of the two interconnects (5, 5′).

7. Electrical connecting element according to any one of the preceding claims, further comprising optical signal transmission means arranged between the core parts (1, 3).

8. Electrical connecting element according to any one of the preceding claims, wherein the two core parts (1, 3) are formed such that, if they are fixed to each other, a cavity (101) is built between the core parts (1, 3), into which cavity (101) elements or components can be integrated.

9. Electrical connecting element according to claim 7, further comprising heat conducting means for conducting heat away from a component integrated into the cavity (101).

10. Electrical connecting element according to any one of the preceding claims, wherein the interconnect or each interconnect (5, 5′) has a thickness not exceeding 500 μm.

11. Electrical connecting element according to any one of the preceding claims, wherein the two core parts are made of a metal.

12. Core for an electrical connecting element being essentially mechanically stiff and comprising two parts (1, 3) which can be fixed to each other and surfaces for attaching interconnects (5, 5′) with conductor paths.

13. Core according to claim 12 being essentially made of a metal, the two parts (1, 3) being formed in a manner that, when they are fixed to each other, a cavity (101) is built, into which components can be integrated.

14. Method for fabricating a build-up comprising passive and/or active components comprising the steps of
providing two core parts which can be fixed to each other
to at least one of the two core parts, attaching an interconnect (5, 5′) with a dielectric substrate layer an with conductor structures thereon,
placing the components (9) on the interconnect (5, 5′),
fixing the two core parts to each other.
